(19) United States
(12) Patent Application Publication
(10) Pub. No.: US 2009/0071537 A1
(43) Pub. Date: Mar. 19, 2009

(54) INDEX TUNED ANTIREFLECTIVE COATING USING A NANOSTRUCTURED METAMATERIAL

(76) Inventors: Ozgur Yavuzcetin, Evanston, IL (US); Mark Thomas Tuominen, Shutesbury, MA (US); Thomas P. Russell, Amherst, MA (US)

Correspondence Address: O''Shea Getz P.C., 1500 MAIN ST. SUITE 912, SPRINGFIELD, MA, 01115, US

(21) Appl. No.: 12/212,240

(22) Filed: Sep. 17, 2008

Related U.S. Application Data
(60) Provisional application No. 60/972,987, filed on Sep. 17, 2007.

(51) Int. Cl. H01L 31/0352; C23F 1/02

(52) U.S. Cl. 136/256; 216/49

(57) ABSTRACT

An anti-reflective layer solar cell/optical medium is provided by nanostructuring the surface of the optical material into which light transmission is desired. The surface of the optical material is etched through a nanoporous polymer film etch mask to transfer the porous pattern to the optical material. The resultant nanostructured layer is an optical metamaterial since it contains structural features much smaller than the wavelength of light and the presence of these structural features change the effective index of refraction by controlling the degree of porosity in the nanostructured layer and also by controlling the thickness of the porous layer.

### PRIORITY INFORMATION

This patent application claims priority from U.S. provisional patent application Ser. No. 60/972,987 filed Sep. 17, 2007 which is hereby incorporated by reference.

### GOVERNMENT RIGHTS

The government may have certain rights in this invention per National Science Foundation grant DMI-0103024.

### BACKGROUND INFORMATION

This invention relates to solar cells, and in particular to a solar cell that includes a nanostructured antireflective structure and a method of forming the same.

In a solar cell, two problems that often limit the performance of the cell are reflection of the incident light and high top grid resistance to the p-n interface. In attempt to increase the amount of light at the desired wavelength to reach the surface of the solar cell, an anti-reflective coating is generally added to the cell. An ideal anti-reflective coating should satisfy two conditions: (a) it should have a specific index of refraction, and (b) a specific thickness.

In an anti-reflecting layer, the thickness t of the film should be:

$$t = \frac{λ}{4 {n}_{1}} ( Phase condition )$$

where:
λ is equal to the wavelength of light; and
n₁ is equal to the material index of refraction.

Another approach to produce anti-reflective coatings, is to pattern the substrate with a periodic structure that includes a dense array of microscope topographic features (e.g., pyramids or columns). See for example the doctoral thesis by Mihai D. Morariu entitled “Pattern Formation by Capillary Instabilities in Thin Films”, University of Groningen, the Netherlands, July 2004. The periodicity must be smaller than the shortest wavelength of the incident light in the visible range. If the pore size is much smaller than the visible wavelengths, the effective refractive index of the nanoporous medium is given by an average over the film. See the paper by Stefan Walheim et al., entitled “Nanophase-Separated Polymer Films as High-Performance Antireflection Coatings”, Science, (520-522), Vol 283, 1999.

The refractive index of a material is related to its density. By introducing porosity, the material density decreases, resulting in a smaller refractive index. The relation between the density and the refractive index of such porous materials is:

$$\frac{{n}_{p}^{2} - 1}{{n}_{c}^{2} - 1} = \frac{{d}_{p}}{{d}_{c}}$$

where nₚ and dₚ are the refractive index and density of the porous material and n_{c} and d_{c} are the refractive index and density of the solid material.

In terms of porosity:

$${n}_{p}^{2} = ( {n}_{c}^{2} - 1 ) ( 1 - \frac{P}{100} ) + 1$$

P is the percentage of porosity.

When P=0% (no pores) [symbol] nₚ=n_{c}

When P=100% (no solid material) [symbol] nₚ=1

In the above identified paper by Stefan Walheim, a nanoporous polymer film is crated by selectively removing one of the two polymers. They observed for pore sizes comparable to or greater than the wavelength of light, the film appears opaque because the light scatters off the porous structure. It was also observed in that paper that if all length scales of the lateral phase morphology lie much below all optical wavelengths, the nanoporous film remains transparent. A remarkable difference is detected when the reflection of a film-covered surface is examined: The nanoporous layer reduces the intensity of reflected light. See German Patent Application DE 198 29 172.8. After coating both sides of the glass slides, they had measured (for one reference wavelength) transmission close to 100%.

However, this prior art technique is disadvantageous because polymers aren't wear resistant and the limitations of the equipment discussed in their paper. Specifically, the atomic force microscopy measurements were carried out on a self-built AFM; layer thicknesses and refractive indices were measured with a single-wavelength ellipsometer (Riss Ellipsometerbau, model EL X-1), and for the ellipsometry measurements, polished silicon wafers were used as substrates; and light transmission spectra were measured with a Perkin Elmers Lambda 40 spectrometer at vertical incidence with an open reference beam.

For a high-index material such as silicon, the surface reflection is about 35% of the incident light in an air environment. For the wavelength where zero reflectivity is desired (600 nm), the thickness of the coating would be 75 nm. Such antireflective coatings must also be highly transparent in the solar spectrum, stable, and resilient to the environment. In their work, they measured the reflectivity of TiO₂ coated silicon wafers. They have also tested on silicon solar cells with AR coatings by measuring I_{sc} and efficiency. They have also fabricated wide-spectrum anti-reflective coatings simply by coating the TiO₂—SiO₂ system by SiO₂ to have a double layer. They have measured a 48% increase in efficiency.

From a theoretical point of view, if the reflection were to be eliminated entirely, there would be about 54% more energy available to the device over the uncoated state. But this is an unattainable increase, the main reason for this is that the zero reflectivity occurs only at one wavelength, not throughout the entire spectrum.

There is a need for an optical material such as a solar cell that includes lower reflectivity.

### SUMMARY OF THE INVENTION

Briefly, according to an aspect of the present invention, an anti-reflective layer solar cell/optical medium is provided by nanostructuring the surface of the optical material into which light transmission is desired. The surface of the optical material is etched through a nanoporous polymer film etch mask to transfer the porous pattern to the optical material. The resultant nanostructured layer is an optical metamaterial since it contains structural features much smaller than the wavelength of light and the presence of these structural features change the effective index of refraction by controlling the degree of porosity in the nanostructured layer and also by controlling the thickness of the porous layer. In addition, the effective surface area of the top layer is increased, which reduces the interfacial resistance of the top layer contact grid in a solar cell application.

A method of forming an antireflective structure on a solar cell substrate includes spin casting a nanoporous Diblock polymer coating on the solar cell substrate and then annealing the Diblock polymer coating located on the substrate to form a nanoporous polymer film etch mask. The substrate surface is then etched the substrate surface using the nanoporous polymer film as an etch mask, and the nanoporous polymer film etch mask is then removed to provide a nanostructured substrate surface, wherein the surface comprises structures smaller than the effective wavelength of the light propagating within the substrate and to a depth equal to about one-quarter of the effective wavelength.

Advantageously, the technique of the present invention is amenable to large scale manufacturing, and provides a wider range of index of refraction as compared to typical deposited films. In addition, the technique is applicable to a wide variety of solar cell materials and other optical materials. The antireflective coating also has improved wear resistance in comparison to the polymeric-based anti-reflective coatings, lower top contact resistance, and reduced likelihood for pinhole defects in comparison to known coating techniques.

These and other objects, features and advantages of the present invention will become more apparent in light of the following detailed description of preferred embodiments thereof, as illustrated in the accompanying drawings.

### BRIEF DESCRIPTION OF THE DRAWINGS

FIGS. 1A-1C are cross sectional pictorial illustrations of the process for creating an index tuned antireflective coating using a nanostructured metamaterial;

FIG. 2 is a flow chart illustration of the processing steps to achieve the index-tuned anti-reflective structure;

FIG. 3 is a pictorial illustration of the process for creating an index tuned antireflective coating using a nanostructured metamaterial; and

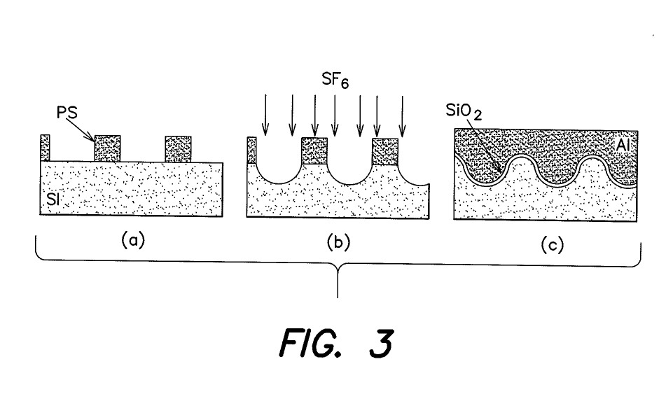

FIG. 4 illustrates an AFM picture of a “semi-finished” solar cell with localized Diblock copolymer ordering.

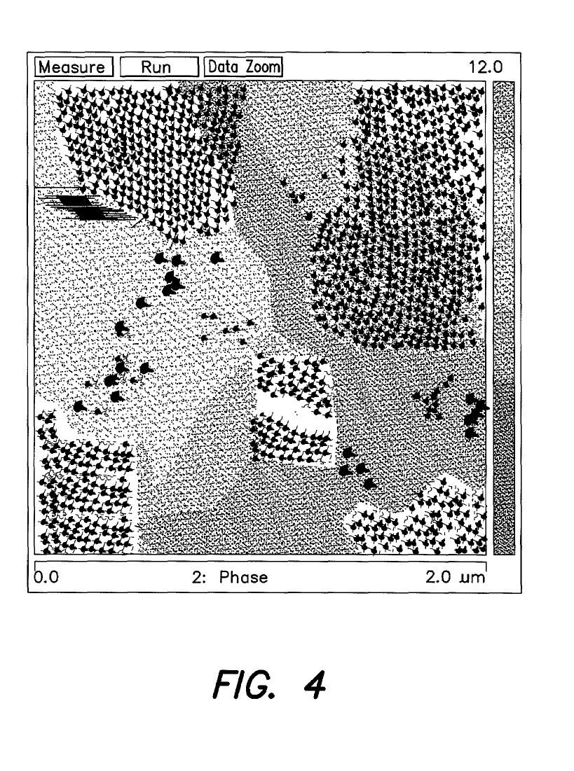

### DETAILED DESCRIPTION OF THE INVENTION

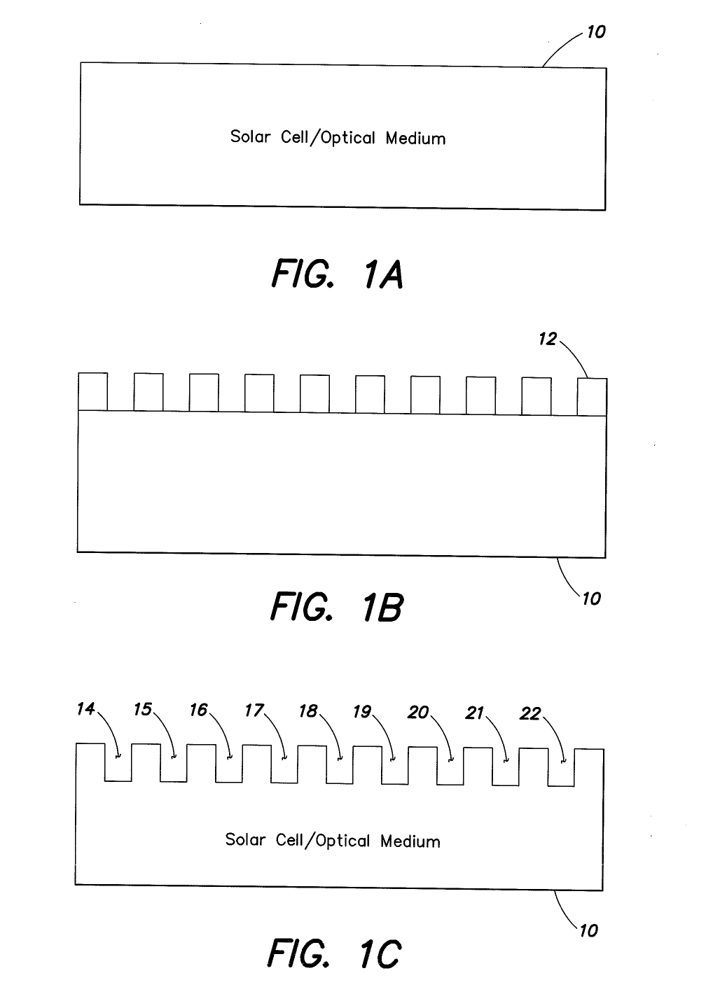

FIGS. 1A-1C pictorially illustrate a process of forming an antireflective layer according to an aspect of the present invention. FIG. 1A illustrates a cross section of a solar cell/optical medium 10 (e.g., Si, GaAs or InGaAs). As shown in FIG. 1B, a nanoporous etch mask 12 is applied to the optical medium 10. A etching agent (not shown) is then applied to create a nanoporous layer of a desired index of refraction and thickness, and the resultant structure is illustrated in FIG. 1C. As shown in FIG. 1C, a plurality of nanopores, for example 14-22, are etched into the optical medium 10 at a porosity that achieves the desired index of refraction and the desired depth. One of ordinary skill in the art will appreciate that the features are not drawn to scale in the interest of clarity and ease of illustration.

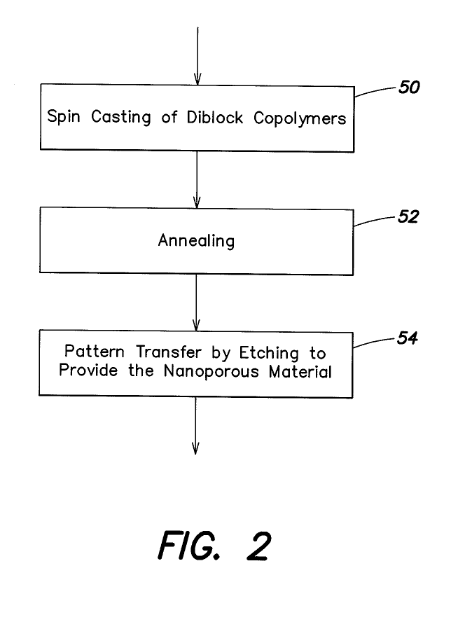

FIG. 2 is a flow chart illustration of the processing steps performed to achieve the index-tuned anti-reflective structure. In step 50, a thin film of a Diblock polymer is spin cast on a silicon substrate. An initial surface treatment to the substrate may be necessary, and such treatments are known in the semiconductor processing arts. Step 52 is performed to anneal the Diblock copolymer film. The paper entitled “Integration of Self-Assembled Diblock Copolymers for Semiconductor Capacitor Fabrication” by C. T. Black et al, Applied Physics Letters, Vol. 79 Number 3, 2001 discloses a technique for using a diblock copolymer thin film as mask for dry etching to roughen a silicon surface, and is hereby incorporated by reference. Step 54 is then performed to pattern transfer by etching in order to provide the nanoporous metamaterial.

Significantly, the present invention provides for a wide range in the index of refraction since the index of refraction of the surface can be tuned for values between solid and air. This is more advantageous than coating the surface with a film since in the case of a coating the index of refraction of the film is limited for values between air and the film. This is especially important for solar cell substrates where a certain window of the spectrum is desired to be non-reflective over the surface. Unlike porous films, the surface will have a periodic structure, which will make the moth-eye effect more intense.

Advantageously, since the nanoporous structure is a part of the substrate, it is much more wear resistant as compared to films. In addition, the surface provided by the present invention provides low top contact resistance in solar cells:

For solar cell applications top contact or grid resistance is a problem and there are studies to lower it (e.g., using buried contacts). However, when the surface is nanotextured according to the present invention, the total surface area will be much more as compared to a flat surface. This provides the advantage of using finer grid lines for the top contact and therefore more light will enter the cell.

Again in solar cell applications, as a way of light trapping, the surface is chemically textured most of the time in order to have micro pyramids that can trap the light better through internal reflections. But this method is done by chemical etching and sometimes pinholes are created between the top n++layer and p-substrate. These pinholes, create short circuit paths and lower the overall efficiency of the cells. But in dry etching; using RIE, the thickness of texturing is much lower and in a more anisotropic controlled way.

It is contemplated that alternatives to a Diblock polymer may include nano imprint lithography, extreme ultraviolet (UV) lithography and nanoporous aluminum oxide. In addition, it is contemplated that alternatives to spin coating include chemical vapor deposition (CVD).

Although the present invention has been illustrated and described with respect to several preferred embodiments thereof, various changes, omissions and additions to the form and detail thereof, may be made therein, without departing from the spirit and scope of the invention.

What is claimed is:

1. A method of forming an anti-reflective structure, comprising:
coating a Diblock copolymer on a solar cell substrate surface;
annealing the Diblock copolymer coating on the substrate surface to form a nanoporous etch mask;
etching the substrate surface using the nanoporous etch mask; and
removing the nanoporous etch mask to provide a nanostructured substrate surface, the nanostructured substrate surface having structures smaller than an effective wavelength of light propagated within the substrate.

2. The method of claim 1, wherein the structures have a depth equal to approximately one quarter of the effective wavelength of light.

3. The method of claim 1, wherein the step of coating comprises spin casting.

4. The method of claim 1, wherein the step of coating comprises chemical vapor deposition.

5. The method of claim 1, further comprising selecting at least one of a porosity and a thickness of the nanoporous etch mask to control an index of refraction in the substrate.

6. The method of claim 1, further comprising treating the substrate surface.

7. The method of claim 1, wherein the step of etching comprises dry etching.

8. The method of claim 1, wherein the structures form a periodic structure.

9. A method of forming an anti-reflective structure, comprising:
depositing a Diblock copolymer on an optical medium surface;
annealing the deposited Diblock copolymer on the medium surface to form a nanoporous etch mask;
etching the medium surface using the nanoporous etch mask; and
removing the nanoporous etch mask to provide a nanostructured medium surface, the nanostructured medium surface having structures smaller than an effective wavelength of light propagated within the medium.

10. The method of claim 9, wherein the structures have a depth equal to approximately one quarter of the effective wavelength of light.

11. The method of claim 9, wherein the step of depositing comprises spin casting.

12. The method of claim 9, wherein the step of depositing comprises chemical vapor deposition.

13. The method of claim 9, further comprising selecting at least one of a porosity and a thickness of the nanoporous etch mask to control an index of refraction in the substrate.

14. The method of claim 9, further comprising treating the medium surface.

15. The method of claim 9, wherein the step of etching comprises dry etching.

16. The method of claim 9, wherein the structures form a periodic structure.

17. A solar cell, comprising:
a solar cell substrate having a surface; and
a plurality of nanostructures etched into the surface of the solar cell substrate, wherein the nanostructures are smaller than an effective wavelength of light and have a depth equal to approximately one quarter of the effective wavelength.

18. The solar cell of claim 17, wherein the plurality of nanostructures form a periodic structure.

19. The solar cell of claim 17, wherein the surface has a low top contact resistance.

20. An optical cell, comprising:
an optical medium having a surface; and
a plurality of nanostructures etched into the surface of the solar cell substrate, wherein the nanostructures are smaller than an effective wavelength of light and have a depth equal to approximately one quarter of the effective wavelength.

21. The optical cell of claim 20, wherein the plurality of nanostructures form a periodic structure.

22. The solar cell of claim 20, wherein the surface has a low top contact resistance.
